(19) United States
(12) Patent Application Publication
(10) Pub. No.: US 2004/0233954 A1
(43) Pub. Date: Nov. 25, 2004

(54) Surface-emitting semiconductor laser element having selective-oxidation type or ion-injection type current-confinement structure, InGaAsp quantum well, and InGaP or InGaAsp barrier layers

(75) Inventor: Toshiro Hayakawa, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/804,216

(22) Filed: Mar. 19, 2004

(30) Foreign Application Priority Data
Mar. 19, 2003 (JP) (PAT) 074904/2003

(51) Int. Cl. H01S 5/00

(52) U.S. Cl. 372/45; 372/46

(57) ABSTRACT

A surface-emitting semiconductor laser element includes a lower AlGaAs multilayer reflection film, an active layer, a current-confinement layer of a selective-oxidation type or an ion-injection type, and an upper AlGaAs multilayer reflection film which are formed above a GaAs substrate in this order in parallel to a surface from which laser light is emitted. The active layer includes: a quantum well made of InGaAsP having a first forbidden band width; and sublayers arranged adjacent to the quantum well and made of InGaP or InGaAsP which has a second forbidden band width greater than the first forbidden band width. The lower and upper AlGaAs multilayer reflection films constitute an optical resonator. The surface-emitting semiconductor laser element further includes a pair of electrodes which inject current into the active layer.

### BACKGROUND OF THE INVENTION

1. Field of the Invention

The present invention mainly relates to a surface-emitting semiconductor laser element which has an emission wavelength in the 780 nm band.

2. Description of the Related Art

The following documents (1) and (2) disclose information related to the present invention.

(1) U.S. Pat. No. 5,633,886

(2) D. Botez, “High-power Al-free coherent and incoherent diode lasers,” Proceedings of SPIE, Vol. 3628 (1999) pp.7

Currently, AlGaAs-based compound surface-emitting semiconductor laser elements (vertical cavity surface-emitting lasers or VCSELs) being formed on a GaAs substrate and having an oscillation wavelength of 850 nm are used as light sources for use in optical links for short-distance high-speed communications. The main reason why the semiconductor laser elements in the above wavelength band are used is that production of semiconductor laser elements with AlGaAs-based compounds is easy, and the propagation loss through quartz fibers which are mainly used currently is low at the above wavelength band.

Con the other hand, it is becoming possible to use POF's (plastic optical fibers) in other short-distance communications performed in the home, in or between devices, in automobiles, and in other applications. The POF's have large core diameters, and are inexpensive and easy to handle. That is, since the core diameters of the POF's are as large as 100 to 1,000 micrometers, alignment is easy, and the cost of transmission/reception modules and fiber connectors can be reduced. In addition, it is easy to shape tips of the POF's and work with the POF's.

Most of the currently available POF's are made of PMMA (polymethyl methacrylate). The wavelength ranges, in which the loss occurring in PMMA POF's is low, are limited. In particular, the wavelengths at which semiconductor lasers enabling high-speed communications are available are limited to only three wavelengths, 650, 780, and 850 nm. Especially, in the case of semiconductor lasers with the wavelengths of 780 and 850 nm, it is possible to perform various operations on a wafer from formation of a resonator to operational tests, and use VCSEL elements as light sources, where the VCSELs can be easily connected to optical fibers. In addition, VCSEL elements having the wavelength of 850 nm can be manufactured more easily than VCSEL elements having the wavelength of 780 nm, and it is reported that the reliability of the VCSEL elements having the wavelength of 780 nm tends to be lower than the reliability of the VCSEL elements having the wavelength of 850 nm. However, the lose that occurs in PMMA POF's at the wavelength of 780 nm is lower than the lose that occurs in PMMA POF's at the wavelength of 850 nm. That is, light having the wavelength of 780 nm can be transmitted over a greater distance than light having the wavelength of 850 nm.

Considering the above circumstances, in order to suppress the lowering of the reliability in the 780 nm band, a VCSEL having a ridge structure, a wavelength in a short wavelength range and not containing aluminum in an active layer has been proposed, for example, in the aforementioned document (1). Generally, when an active layer is made of AlGaAs containing Al in order to shorten the wavelength, the laser emission efficiency is lowered by increase in non-radiative recombination centers which are produced by mixing of oxygen into AlGaAs during processes for growing crystals and producing elements. In the VCSEL disclosed in document (1), in order to prevent the lowering of laser emission efficiency, the active layer region is constituted by an Al-free GaAsP quantum well and GaInP barrier layers. In addition, since GaAsP does not lattice-match with the GaAs substrate, and causes tensile strain, the total strain is reduced by GaInP which causes compressive strain.

On the other hand, edge-emitting stripe lasers containing a Fabry-Perot resonator and an active region made of AlGaAs are widely used as light sources in CD and CD-R devices. Recently, in order to increase the recording rates in CD-R devices and the like, even laser elements having a high output power exceeding 150 mW have come into use. In the case of edge-emitting stripe laser elements, it is known that Al-free active layers are beneficial for achieving high reliability, for example, as indicated in the aforementioned document (2). The most conceivable reason for the benefit of the Al-free active layers is that the reliability of the edge-emitting stripe lasers mainly depends on the stability of cleaved end faces, and the end faces are likely to be oxidized.

Further, most of the current AlGaInP-based compound high-power short-wavelength semiconductor lasers have an NAM (non-absorbing mirror) structure, in which light absorption at end faces is suppressed. However, due to recent improvements in crystal growth systems and increases in the purities of raw materials, the quality of AlGaAs crystals are extremely high. Therefore, it is difficult to consider that the quality of AlGaAs crystals is the primary cause of the degradation of the AlGaInP-based compound high-power short-wavelength semiconductor lasers. In particular, in the case of VCSELs, since no cleaved end face exists, and no active layer is exposed, no degradation is caused by an end face.

However, in the ridge type VCSELs as disclosed in document (1), portions of an active region are removed by etching. Therefore, there is a possibility that oxidation of surfaces exposed by the removal may affect the reliability of the VCSELs. In order to prevent the oxidation, VCSELs having an ion-injection type or selective-oxidation type current-confinement structure are widely used. In the ion-injection type or selective-oxidation type current-confinement structure, no portion of an active region is removed by etching. In VCSELs having an ion-injection type current-confinement structure, current is confined in an oscillation region located at the center of an active region by injecting ions such as protons to the depth of the upper boundary of the active region except for a current-injection region so as to insulate the proton-injected region. In VCSELs having a selective-oxidation type current-confinement structure, current is confined by selectively oxidizing an already formed, AlAs or aluminum-rich AlGaAs layer from the periphery so as to insulate the oxidized portion of the AlAs or aluminum-rich AlGaAs layer. In the latter case, it is necessary to etch off peripheral portions of semiconductor layers. However, since the selectively oxidized portion extends to a great depth from an area of the active layer exposed by the etching, there is almost no influence of non-radiative recombination occurring in the exposed area of the active layer. Alternatively, it is possible to stop the etching performed for the selective oxidation, above the active layer so as not to expose the active layer.

In the above circumstances, even in the case of VCSELs having an active layer made of AlGaAs, the possibility that degradation of crystal quality lowers the reliability of the VCSELs is considered to be very low. However, even in the case of VCSELs having an AlGaAs active layer and an ion-injection type or selective-oxidation type current-confinement structure, VCSELs having an AlGaAs active layer with higher Al composition and emitting laser light at the wavelength of 780 nm are degraded faster than VCSELs emitting laser light at the wavelength of 850 nm.

Further, the present applicants have found that internal stress occurs in the ion-injection type or selective-oxidation type VCSELs, which are currently becoming mainstream, since the oxidized current-confinement layer becomes a completely different material (e,g., Al₂O₃) from the crystals around the oxidized current-confinement layer. The internal stress lowers crystal quality and reliability of the laser.

### SUMMARY OF THE INVENTION

The present invention has been developed in view of the above circumstances.

It is an object of the present invention is to provide a highly reliable surface-emitting semiconductor laser element which emits laser light in an oscillation-wavelength band of 730 to 820 nm.

According to the present invention, there is provided a surface-emitting semiconductor laser element which emits laser light from a surface. The surface-emitting semiconductor laser element comprises: a GaAs substrate; semiconductor layers which are formed above the GaAs substrate in parallel to, the above surface; and a pair of electrodes which inject current into an active layer. The semiconductor layers include: a lower mirror which is realized by a semiconductor multilayer film, is formed above the GaAs substrate, and constitutes an optical resonator; the active layer formed above the lower mirror; a current-confinement layer of a selective-oxidation type or an ion-injection type formed above the active layer; and an upper mirror which is realized by a semiconductor multilayer film, is formed above the current-confinement layer, and constitutes the optical resonator. The active layer includes: a quantum well made of InGaAsP having a first forbidden band width; and sublayers arranged adjacent to the quantum well and made of InGaP or InGaAsP which has a second forbidden band width greater than the first forbidden band width. The lower mirror and the upper mirror are made of AlGaAs.

The selective-oxidation type current-confinement layer is a layer which is formed to confine current injected into the active layer, by selectively oxidizing portions of a semiconductor layer which is easily subject to selective oxidation (e.g., an AlAs layer or an aluminum-rich AlGaAs layer) except for a current-injection area so as to insulate or semi-insulate the portions of the semiconductor layer by the oxidation.

The ion-injection type current-confinement layer is a layer which is formed to confine current injected into the active layer, by injecting ions such as protons into portions of a semiconductor layer except for a current-injection region so as to insulate or semi-insulate the portions of the semiconductor layer by the injection.

Preferably, the surface-emitting semiconductor laser element according to the present invention may also have one or any possible combination of the following additional features (i) to (ix).

(i) Each of the quantum well and the sublayers has such a composition so as to lattice-match with GaAs.

When the GaAs substrate has a lattice constant cₛ, and a layer grown above the substrate has a lattice constant c, and the absolute value of the amount (c−cₛ)/cₛ is equal to or smaller than 0.003, the layer lattice-matches with the substrate.

(ii) The quantum well has such a composition so as to cause compressive strain with respect to GaAs, and each of the sublayers has such a composition so as to lattice-match with GaAs,

When a layer grown above the GaAs substrate has a lattice constant c greater than the lattice constant c) of the GaAs substrate, and the amount (c−cₛ)/cₛ is greater than 0.003, the layer causes compressive strain with respect to GaAs.

(iii) The quantum well has such a composition so as to cause compressive strain with respect to GaAs, and each of the sublayers has such a composition so as to cause tensile strain with respect to GaAs.

When a layer grown above the GaAs substrate has a lattice constant c smaller than the lattice constant cₛ of the GaAs substrate, and the amount (c−cₛ)/cₛ is smaller than −0.003, the layer causes tensile strain with respect to GaAs.

(iv) The quantum well has such a composition so as to cause tensile strain with respect to GaAs, and each of the sublayers has such a composition so as to lattice-match with GaAs.

(v) The quantum well has such a composition so as to cause tensile strain with respect to GaAs, and each of the sublayers has such a composition so as to cause compressive strain with respect to GaAs.

(vi) The sublayers are barrier layers.

(vii) The sublayers are spacer layers.

(viii) The laser light has a wavelength in a range from 730 to 820 nm.

(ix) The laser light has a wavelength in a range from 770 to 800 nm.

The advantages of the present invention will be described below.

Since the active layer in the surface-emitting semiconductor laser element according to the present invention includes the quantum well made of InGaAsP and the sublayers made of InGaP or InGaAsP and arranged adjacent to the quantum well, it is possible to prevent the influence of strain caused by the current-confinement layer of the selective-oxidation type or the ion-injection type. Therefore, lowering of crystal quality caused by the strain can be prevented, and high reliability can be achieved.

The present invention having the above advantages has been made based on a finding by the applicants that active layers made of InGaAsP and InGaP sublayers in surface-emitting semiconductor laser elements are resistant to strain occurring in layers outside the active layers from the viewpoint of reliability, as described in detail below.

The present applicants have produced two semiconductor laser elements (A) and (B) by MOCVD (metal organic chemical vapor deposition).

In the semiconductor laser element (A), an n-type GaAs buffer layer (having a thickness of 0.2 micrometers and being doped with Si of 1×10¹⁸ cm⁻³), an n-type Al_{0.6}Ga_{0.4}As cladding layer (having a thickness of 1.5 micrometers and being doped with Si of 8×10¹⁷ cm⁻³), an undoped Al_{0.3}Ga_{0.7}As optical guide layer (having a thickness of 0.2 micrometers), an undoped Al_{0.08}Ga_{0.92}As single-quantum-well active layer (having a thickness of 10 micrometers and a wavelength of 810 nm and lattice-matching with the GaAs substrate), an undoped Al_{0.3}Ga_{0.7}As optical guide layer (having a thickness of 0.2 micrometers), a p-type Al_{0.6}Ga_{0.4}AS cladding layer (having a thickness of 1.5 micrometers and being doped with Zn of 1×10¹⁸ cm⁻³), a p-type GaAs cap layer (having a thickness of 0.2 micrometers and being doped with Zn of 5×10¹⁸ cm⁻³), a SiO₂ film having a stripe opening corresponding to a current-injection region and having a width of 50 micrometers, and a p electrode made of Ti/Pt/Au are formed on an n-type GaAs substrate (doped with Si of 1×10¹⁸ cm⁻³). In addition, an n electrode made of AuGe/Au is formed on the back surface of the substrate.

The semiconductor laser element (a) has an identical structure to the semiconductor laser element (A) except that the optical guide layers are made of InGaP, and the quantum-well active layer is made of InGaAsP. Both of the semiconductor laser elements (A) and (B) have a resonator length of 750 micrometers. In each of the semiconductor laser elements (A) and (B), the forward end face is coated so as to have a reflectance of 30%, and the back end face is coated so as to have a reflectance of 95%. In addition, the bonding surface of each of the semiconductor laser elements (A) and (B) is bonded to a heat sink made of CuW with AuSn solder.

The applicants have measured a change of a driving current in each of the semiconductor laser elements (A) and (B) over time during an aging test performed at the ambient temperature of 50° C. with a constant output power of 500 mW, as indicated in FIG. 4. Although all samples of the semiconductor laser element (A) stop oscillation in 1,000 hours, all samples of the semiconductor laser element (B) stably operate for a long time. However, when indium, which is soft and plastically deformable, is used as the soldering material, the stress imposed on the chips is small, and therefore the above difference in the lifetime between the semiconductor laser elements (A) and (B) is not observed. That is, the above difference in the lifetime is caused by external stress imposed by the AuSn solder, and the results of the aging tests indicated in FIG. 4 show that the semiconductor laser element in which the optical guide layers are made of InGaP, and the quantum-well active layer is made of InGaAsP is more resistant to the external stress than the semiconductor laser element in which the quantum-well active layer is made of AlGaAs.

In addition, according to the present invention, since the sublayers made of InGaP or InGaAsP are arranged adjacent to the quantum well, it is possible to prevent formation of a region where AlGaAs (of which the upper and lower mirrors are made) and InGaAsP (of which the quantum well is made) are in contact with each other. Since it is impossible to form a high-quality crystal in the region where AlGaAs and InGaAsP are in contact with each other, high reliability can be achieved by the prevention of formation of such a region.

Further, when each of the quantum well and the sublayers has such a composition so as to lattice-match with GaAs, it is possible to achieve satisfactory crystal quality and high reliability.

When the quantum well has such a composition so as to cause compressive strain with respect to GaAs, and each of the sublayers has such a composition so as to cause tensile strain with respect to GaAs, it is possible to compensate for the compressive strain in the quantum well with the tensile strain in the sublayers. Therefore, the crystal quality is improved, and satisfactory laser characteristics are achieved.

When the quantum well has such a composition o as to cause tensile strain with respect to GaAs, and each of the sublayers has such a composition so as to cause compressive strain with respect to GaAs, it is possible to compensate for the tensile strain in the quantum well with the compressive strain in the sublayers. Therefore, the crystal quality is improved, and satisfactory laser characteristics are achieved.

### BRIEF DESCRIPTION OF THE DRAWINGS

FIG. 1 is a cross-sectional view of a surface-emitting semiconductor laser element according to a first embodiment of the present invention.

FIG. 2 is a cross-sectional view of an example of a variation of the surface-emitting semiconductor laser element according to the first embodiment of the present invention.

FIG. 3 is a cross-sectional view of a surface-emitting semiconductor laser element according to a second embodiment of the present invention.

FIG. 4 is a graph indicating results of aging reliability tests of a semiconductor laser element (A) having an AlGaAs active layer and a semiconductor laser element (B) having an InGaAsP active layer.

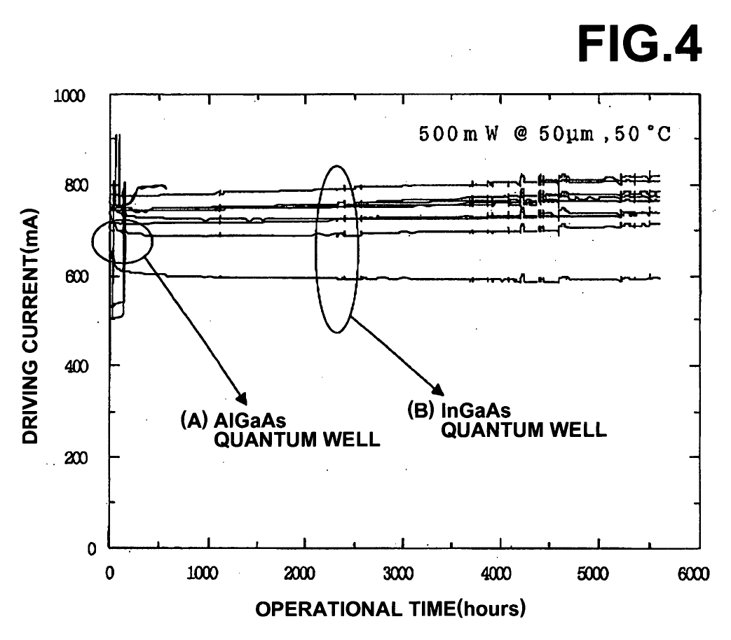

### DESCRIPTION OF PREFERRED EMBODIMENTS

Embodiments of the present invention will be described in detail below with reference to the attached drawings.

### First Embodiment

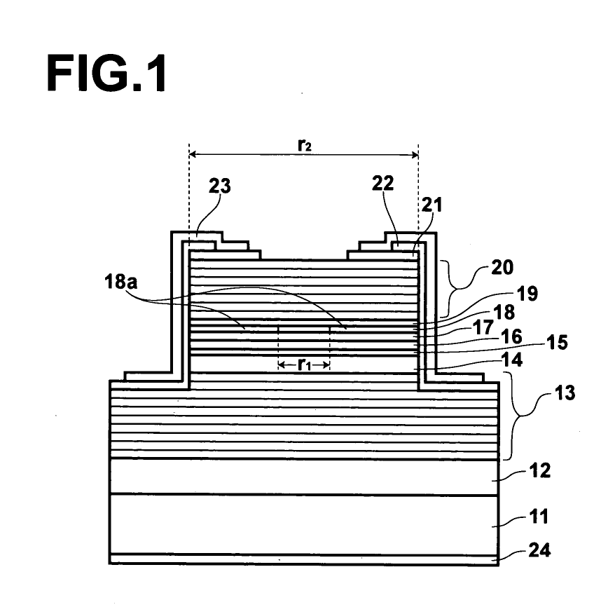

First, the surface-emitting semiconductor element according to the first embodiment of the present invention will be described below with reference to FIG. 1, which shows a cross section of the surface-emitting semiconductor element.

As illustrated in FIG. 1, first, an n-type GaAs buffer layer 12 (which has a thickness of 100 nm and is doped with Si of 1×10¹⁸ cm⁻³), an n-type Al_{0.9}Ga_{0.1}AS/Al_{0.3}Ga_{0.7}As lower semiconductor multilayer reflection film 13, an undoped InGaP spacer layer 14, a quantum-well active layer 15, an undoped InGaP spacer layer 16, a p-type Al_{0.6}Ga_{0.5}As spacer layer 17 (doped with C of 8×10¹⁷ cm⁻³) a p-type AlAs layer 18 (which has a thickness corresponding to a quarter wavelength and is doped with C of 2×10¹⁸ cm⁻³), a p-type Al_{0.5}Ga_{0.5}As spacer layer 19, a p-type Al_{0.9}Ga_{0.1}As/Al_{0.3}Ga_{0.7}As upper semiconductor multilayer reflection film 20, and a p-type GaAs contact layer 21 (which has a thickness of 10 nm and is doped with C of 5×10¹⁹ cm⁻³) are formed on an n-type GaAs substrate 11 by MOCVD. The n-type Al_{0.9}Ga_{0.1}As/Al_{0.3}Ga_{0.7}As lower semiconductor multilayer reflection film 13 is constituted by 38.5 periods of alternating layers of a high-refractive-index film and a low-refractive-index film each having a thickness corresponding to a quarter wavelength and being doped with Si of 1×10¹⁸ cm⁻³. The quantum-well active layer 15 is constituted by three undoped InGaAsP quantum-well layers each having a thickness of 10 nm and an oscillation wavelength of 780 nm and two undoped InGaP barrier layers each having a thickness of 5 nm. The p-type Al_{0.9}Ga_{0.1}As/Al_{0.3}Ga_{0.7}As upper semiconductor multilayer reflection film 20 is constituted by 28 periods of alternating layers of a high-refractive-index film and a low-refractive-index film each having a thickness corresponding to a quarter wavelength and being doped with C of 2×10¹⁸ cm⁻³.

In the first embodiment, all of the layers made of InGaP or InGaAsP have such composition so as to lattice-match with the GaAs substrate.

Next, an area of the p-type GaAs contact layer 21 corresponding to an emission region is removed by etching. In order to form an oscillation region, portions of the above semiconductor layers except for a cylindrical region having a diameter r₂ of 50 micrometers are removed by etching to a mid-thickness of the n-type Al_{0.9}Ga_{0.1}As/Al_{0.3}Ga_{0.7}As lower semiconductor multilayer reflection film 13. Then, heat treatment is performed at 390° C. for ten minutes in a furnace into which heated steam is introduced, so that a portion 18a of the p-type AlAs layer 18 excluding a current-injection region is selectively oxidized, i.e., the round-shaped current-injection region is formed. The current-injection region has a diameter r₁ of 12 micrometers.

Thereafter, a SiO₂ protection film 22 is formed over the areas which are exposed by the etching performed for producing the above cylindrical region, and then a portion of the SiO₂ protection film 22 corresponding to the current-injection region is removed. Subsequently, a p electrode 23 made of Ti/Pt/Au is formed on the p-type GaAs contact layer 21, and an n electrode 24 made of AuGe/Ni/Au is formed on the back surface of the n-type GaAs substrate 119. That is, the p electrode 23 is formed by depositing Ti, Pt, and Au in this order, and the n electrode 24 is formed by depositing AuGe, Ni and Au in this order.

In the above structure, the spacer layers are arranged so as to adjust the optical thickness of the layers between the lower and upper semiconductor multilayer reflection films and locate a loop portion of a standing wave over the active layer, and have an effect of lowering the threshold.

In the first embodiment, the spacer layers include the undoped InGaP spacer layer 14 which is arranged on the substrate side of the active layer 15, and the undoped InGaP spacer layer 16, the p-type Al_{0.5}Ga_{0.5}As spacer layer 17, and the p-type Al_{0.5}Ga_{0.5}As spacer layer 19 which are arranged on the opposite side of the active layer 15. If layers made of AlGaAs (such as the n-type Al_{0.9}Ga_{0.1}As/Al_{0.3}Ga_{0.7}As lower semiconductor multilayer reflection film 13 and the p-type Al_{0.5}Ga_{0.5}As spacer layer 17) exist in contact with the undoped InGaAsP quantum-well layer in the quantum-well active layer 15, it is impossible to form satisfactory crystal interfaces. However, since the undoped InGaP spacer layer 14 and the undoped InGaP spacer layer 16 are provided in the first embodiment, it is possible to make the interfaces with the undoped InGaAsP quantum-well layer have satisfactory quality, and improve the reliability of the surface-emitting semiconductor laser element.

In addition, since the p-type AlAs layer 18 having a function of a current-confinement layer is arranged between the p-type Al_{0.5}Ga_{0.5}As spacer layer 17 and the p-type Al_{0.5}Ga_{0.5}As spacer layer 19, the selective oxidation characteristics at the interfaces between the AlGaAs layers and the Ales layer become satisfactory, and highly precise current-confinement is enabled.

As described above, the surface-emitting semiconductor laser element according to the first embodiment comprises the n-type GaAs substrate 11, the semiconductor layers formed on the n-type GaAs substrate 11, and the pair of electrodes (the p electrode 23 and the n electrode 24) for injecting current into the quantum-well active layer 15, where the semiconductor layers include the n-type GaAs buffer layer 12, the n-type Al_{0.9}Ga_{0.1}As/Al_{0.3}Ga_{0.7}AS lower semiconductor multilayer reflection film 13, the undoped InGaP spacer layer 14, the quantum-well active layer 15, the undoped InGaP spacer layer 16, the p-type Al_{0.5}Ga_{0.5}As spacer layer 17, the p-type AlAs layer 18, the p-type Al_{0.5}Ga_{0.5}As spacer layer 19, the p-type Al_{0.9}Ga_{0.1}As/Al_{0.3}Ga_{0.7}As upper semiconductor multilayer reflection film 20, and the p-type GaAs contact layer 21 which are formed in this order, the quantum-well active layer 15 includes the undoped InGaAsP quantum-well layers and the undoped InGaP barrier layers, and the portion 18a of the p-type AlAs layer 18 other than the current-injection region is oxidized. Laser light is emitted from the exposed surface of the p-type Al_{0.9}Ga_{0.1}As/Al_{0.3}Ga_{0.7}As upper semiconductor multilayer reflection film 20. The n-type Al_{0.9}Ga_{0.1}AS/Al_{0.3}Ga_{0.7}AS lower semiconductor multilayer reflection film 13 and the p-type Al_{0.9}Ga_{0.1}As/Al_{0.3}Ga_{0.7}AS upper semiconductor multilayer reflection film 20 realize mirrors constituting an optical resonator.

Since the AlAs layer 18 is selectively oxidized, Al₂O₃ is produced, and strain occurs. However, since the influence of the strain can be suppressed by the provision of the undoped InGaAsP quantum-well layers and the undoped InGaP barrier layers, it is possible to achieve high reliability.

The surface-emitting semiconductor laser element according to the first embodiment may be modified as follows.

(1) Instead of p-type Al_{0.5}Ga_{0.5}As, both of the p-type spacer layers 17 and 19 may be made of InGaP or InGaAsP. Alternatively, the p-type spacer layers 17 and 19 may be made of a combination of InGaP and InGaAsP.

(2) The spacer layers 14 and 16 may be made of undoped InGaAsP, instead of undoped InGaP.

(3) Instead of providing the undoped InGaP spacer layers 14 and 16, it is possible to arrange additional two barrier layers made of undoped InGaP or InGaAsP on the outermost sides of the quantum-well active layer 15.

(4) Although the n electrode 24 is formed on the back surface of the n-type GaAs substrate 11 in the first embodiment, alternatively the etching for producing the aforementioned cylindrical region may be performed to such a depth so as to expose one of the n-type layers, and form an n electrode on the exposed n-type layer. For example, it is possible to expose the n-type Al_{0.9}Ga_{0.1}As/Al_{0.3}Ga_{0.7}As lower semiconductor multilayer reflection film 13 and form the n electrode on the exposed surface of the lower semiconductor multilayer reflection film 13.

(5) Although the layers constituting the surface-emitting semiconductor laser element according to the first embodiment are grown by MOCVD, the layers may be formed by molecular beam epitaxy (MBE) using a solid or gas source.

(6) Although the number of quantum-well layers in the surface-emitting semiconductor laser element according to the first embodiment is three, the surface-emitting semiconductor laser element according to the first embodiment may include any number or quantum-well layers.

(7) Instead of SiO₂, the protection film 22 may be made of Al₂O₃, SiₓN_{y} or the like.

(8) The p electrode may be made by depositing chromium and gold in this order, or depositing AuGe and gold in this order.

(9) The n electrode may be made by depositing AuGe and gold in this order.

(10) Although the p-type AlAs layer 18 other than the current-injection region is selectively oxidized for current confinement in the first embodiment, i.e., the surface-emitting semiconductor laser element according to the first embodiment includes a selective-oxidation type current-confinement structure, alternatively, it is possible to adopt an ion-injection type current-confinement structure, in which regions other than the current-injection region are insulated by injecting protons or the like into the regions other than the current-injection region, or semi-insulated by injecting other ions into the above regions other than the current-injection region.

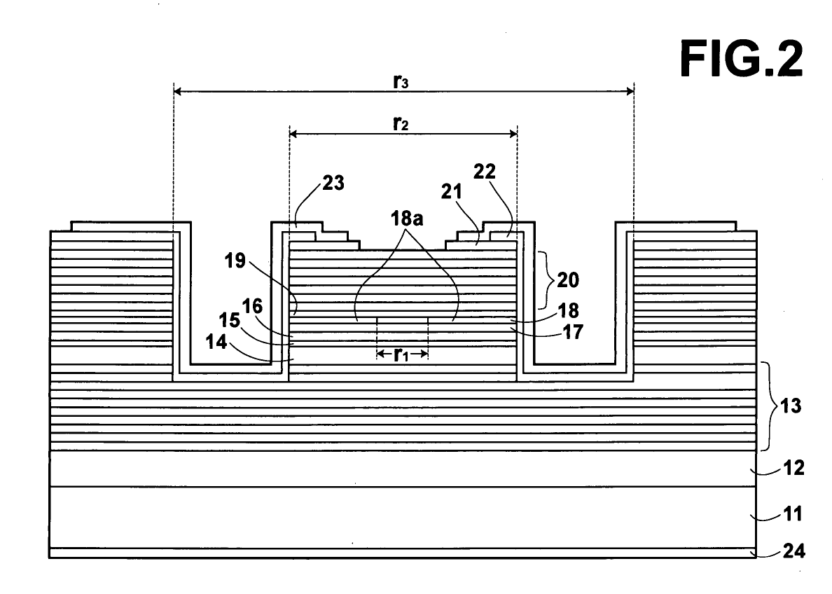

(11) Although, in the surface-emitting semiconductor laser element according to the first embodiment, the oscillation region having the cylindrical shape protrudes upward as illustrated in FIG. 1, alternatively, it is possible to realize the oscillation region by forming a doughnut-shaped trench around the oscillation region, and leaving the semiconductor layers on the outer side of the doughnut-shaped trench so that the surface-emitting semiconductor laser element except for the doughnut-shaped trench has substantially a uniform height. For example, the doughnut-shaped trench has an inner diameter r₂ of 50 micrometers and an outer diameter r₃ of 80 micrometers as illustrated in FIG. 2. Since the portion of the surface-emitting semiconductor laser element on the outer side of the doughnut-shaped trench has the same height as the oscillation region, the surface-emitting semiconductor laser element having the structure illustrated in FIG. 2 is advantageous for handling of the element during a manufacturing process, wire bonding at the time of mounting, and the like.

(12) Although only one oscillation region is arranged in the surface-emitting semiconductor laser element according to the first embodiment, it is possible to arrange a plurality of oscillation regions in a single element by forming a plurality of doughnut-shaped trenches.

### Second Embodiment

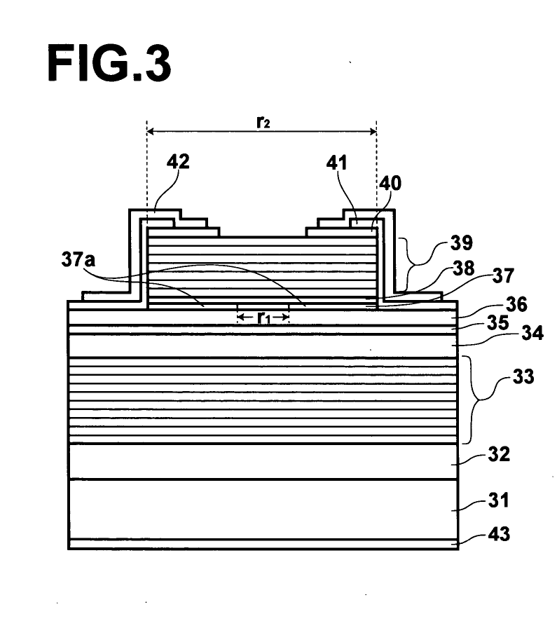

First, the surface-emitting semiconductor element according to the second embodiment of the present invention will be described below with reference to FIG. 3, which shows a cross section of the surface-emitting semiconductor element.

As illustrated in FIG. 3, first, an n-type GaAs buffer layer 32 (which has a thickness of 100 nm and is doped with Si of 1×10¹⁸ cm⁻³), an n-type Al_{0.9}Ga_{0.1}As/Al_{0.3}Ga_{0.7}As lower semiconductor multilayer reflection film 33, an undoped InGaP spacer layer 34, a quantum-well active layer 35, an undoped InGaP spacer layer 36, a p-type AlAs layer 37 (which has a thickness corresponding to a quarter wavelength and is doped with c of 2×10¹⁸ cm⁻³), a p-type Al_{0.5}Ga_{0.5}As spacer layer 38, a p-type Al_{0.9}Ga_{0.1}AS/Al_{0.3}Ga_{0.7}As upper semiconductor multilayer reflection film 39, and a p-type GaAs contact layer 40 (which has a thickness of 10 nm and is doped with C of 1×10²⁰ cm⁻³) are formed in this order on an n-type GaAs substrate 31 by MOCVD. The n-type Al_{0.9}Ga_{0.1}As/Al_{0.3}Ga_{0.7}As lower semiconductor multilayer reflection film 33 is constituted by 40.5 periods of alternating layers of a high-refractive-index film and a low-refractive-index film each having a thickness corresponding to a quarter wavelength and being doped with Si of 1×10¹⁸ cm⁻³. The quantum-well active layer 35 is constituted by four undoped InGaAsP quantum-well layers each having a thickness of 8 nm and an oscillation wavelength of 780 nm and three undoped InGaP barrier layers each having a thickness of 5 nm. The p-type Al_{0.9}Ga_{0.1}As/Al_{0.3}Ga_{0.7}As upper semiconductor multilayer reflection film 39 is constituted by 29 periods of alternating layers of a high-refractive-index film and a low-refractive-index film each having a thickness corresponding to a quarter wavelength and being doped with C of 2×10¹⁸ cm⁻³.

In the second embodiment, all of the layers made of InGaP or InGaAsP have such composition so as to lattice-match with the GaAs substrate.

Next, an area of the p-type GaAs contact layer 40 corresponding to an emission region is removed by etching. In order to form an oscillation region, portions of the semiconductor layers except for a cylindrical region having a diameter r₂ of 30 micrometers are removed by etching to the upper boundary of the p-type Al_{0.5}Ga_{0.5}AS spacer layer 36. Then, heat treatment is performed at 390° C. for eight minutes in a furnace into which heated steam is introduced, so that a portion of the p-type AlAs layer 37 excluding a current-injection region is selectively oxidized, i.e., the round-shaped current-injection region is formed, The current-injection region has a diameter r₁ of 8 micrometers.

Thereafter, a SiO₂ protection film 41 is formed over the areas which are exposed by the etching performed for producing the above cylindrical region, and then a portion of the SiO₂ protection film 41 corresponding to the current-injection region is removed. Subsequently, a p electrode 42 made of Ti/Pt/Au is formed on the p-type Gads contact layer 40, and an n electrode 43 made of AuGe/Ni/Au is formed on the back surface of the n-type GaAs substrate 31. That is, the p electrode 42 is formed by depositing Ti, Pt, and Au in this order, and the n electrode 43 is formed by depositing AuGe, Ni and Au in this order.

In the above structure, the p-type Al_{0.5}Ga_{0.5}As spacer layer 38 is arranged so as to adjust the optical thickness of the layers between the lower and upper semiconductor multilayer reflection films 33 and 39 and locate a loop portion of a standing wave over the active layer.

As described above, the surface-emitting semiconductor laser element according to the second embodiment comprises the n-type GaAs substrate 31, the semiconductor layers formed on the n-type GaAs substrate 31, and the pair of electrodes (the p electrode 42 and the n electrode 43) for injecting current into the quantum-well active layer 35, where the semiconductor layers include the r-type GaAs buffer layer 32, the n-type Al_{0.9}Ga_{0.1}As/Al_{0.3}Ga_{0.7}As lower semiconductor multilayer reflection film 33, the undoped InGaP spacer layer 34, the quantum-well active layer 35, the undoped InGaP spacer layer 36, the p-type AlAs layer 37, the p-type Al_{0.5}Ga_{0.5}As spacer layer 38, the p-type Al_{0.9}Ga_{0.1}As/Al_{0.3}Ga_{0.7}AS upper semiconductor multilayer reflection film 39, and the p-type GaAs contact layer 40 which are formed in this order, the quantum-well active layer 35 includes the undoped InGaAsP quantum-well layers and the undoped InGaP barrier layers, and the portion of the p-type AlAs layer 37 other than the current-injection region is oxidized. Laser light is emitted from the exposed surface of the p-type Al_{0.9}Ga_{0.1}As/Al_{0.3}Ga_{0.7}As upper semiconductor multilayer reflection film 39. The n-type Al_{0.9}Ga_{0.1}As/Al_{0.3}Ga_{0.7}As lower semiconductor multilayer reflection film 33 and the p-type Al_{0.9}Ga_{0.1}As/Al_{0.3}Ga_{0.7}As upper semiconductor multilayer, reflection film 39 realize mirrors constituting an optical resonator.

Similar to the first embodiment, acceleration of deterioration due to strain in the current-confinement layer can be prevented by the provision of the undoped InGaAsP quantum-well layers and the undoped InGaP barrier layers in the active layer, Therefore, it is possible to achieve high reliability.

### Variations of First and Second Embodiments

The surface-emitting semiconductor laser elements according to the first and second embodiments may be modified as follows.

(1) Although the barrier layers in the first and second embodiments are made of InGaP, which in a ternary mixed crystal, alternatively, all or a portion of the barrier layers may be made of InGaAsP, which is a quaternary mixed crystal. In the case where all or a portion of the barrier layers are made of InGaAsP containing some quantity (not exceeding about 5%) of As, it is possible to make the flatness of the surface of grown InGaAsP higher than that of InGaP by adjusting a crystal growth condition such as growth temperature or crystal orientation. Therefore, in this case, the high flatness increases the emission efficiency, and decreases the deterioration rate.

(2) Although each of the quantum-well layers and the barrier layers in the first and second embodiments is made of InGaAsP or InGaP which has such a composition so as to lattice-match with GaAs, alternatively, it is possible to form each of the quantum-well layers of InGaAsP which has such a composition so as to cause compressive strain with respect to GaAs, and each of the barrier layers of InGaAsP or InGaP which has such a composition so as to lattice-match with GaAs.

In a second alternative, it is possible to form each of the quantum-well layers of InGaAsP which has such a composition so as to cause compressive strain with respect to GaAs, and each of the barrier layers of InGaAsP or InGaP which has such a composition so as to cause tensile strain with respect to GaAs.

In a third alternative, it is possible to form each of the quantum-well layers of InGaAsP which has such a composition so as to cause tensile strain with respect to GaAs, and each of the barrier layers of InGaAsP or InGaP which has such a composition so as to lattice-match with GaAs.

In a fourth alternative, it is possible to form each of the quantum-well layers of InGaAsP which has such a composition so as to cause tensile strain with respect to GaAs, and each of the barrier layers of InGaAsP or InGaP which has such a composition so as to cause compressive strain with respect to GaAs.

### Additional Matters

(i) According to the present invention, the reliability of VCSELs having a selective-oxidation type or ion-injection type current-confinement structure (which are superior in performance and suitable for mass production) can be improved, Therefore, it is possible to promote realization of high-speed optical-fiber communications at transmission rates exceeding 1 Gbps in the automotive, home, HDTV, and other applications.

(ii) In addition, all of the contents of the Japanese patent application No. 2003-074904 are incorporated into this specification by reference.

What is claimed is:

1. A surface-emitting semiconductor laser element for emitting laser light from a surface, comprising:
a GaAs substrate;
semiconductor layers which are formed above said GaAs substrate in parallel to said surface, and include,
a lower mirror which is realized by a semiconductor multilayer film, is formed above said GaAs substrate, and constitutes an optical resonator,
an active layer formed above said lower mirror,
a current-confinement layer of one of a selective-oxidation type and an ion-injection type formed above said active layer, and
an upper mirror which is realized by a semiconductor multilayer film, is formed above said current-confinement layer, and constitutes said optical resonator; and
a pair of electrodes which inject current into said active layer;
wherein said active layer includes,
a quantum well made of InGaAsP having a first forbidden band width, and
sublayers arranged adjacent to said quantum well and made of one of InGaP and InGaAsP which has a second forbidden band width greater than said first forbidden band width; and
said lower mirror and said upper mirror are made of AlGaAs.

2. A surface-emitting semiconductor laser element according to claim 1, wherein each of said quantum well and said sublayers has such a composition so as to lattice-match with GaAs.

3. A surface-emitting semiconductor laser element according to claim 1, wherein said quantum well has such a composition so as to cause compressive strain with respect to GaAs, and each of said sublayers has such a composition so as to lattice-match with GaAs.

4. A surface-emitting semiconductor laser element according to claim 1, wherein said quantum well has such a composition so as to cause compressive strain with respect to GaAs, and each of said sublayers has such a composition so as to cause tensile strain with respect to GaAs.

5. A surface-emitting semiconductor laser element according to claim 1, wherein said quantum well has such a composition so as to cause tensile strain with respect to GaAs, and each of said sublayers has such a composition so as to lattice-match with GaAs.

6. A surface-emitting semiconductor laser element according to claim 1, wherein said quantum well has such a composition so as to cause tensile strain with respect to GaAs, and each of said sublayers has such a composition so as to cause compressive strain with respect to GaAs.

7. A surface-emitting semiconductor laser element according to claim 1, wherein said sublayers are barrier layers.

8. A surface-emitting semiconductor laser element according to claim 1, wherein said sublayers are spacer layers.

9. A surface-emitting semiconductor laser element according to claim 1, wherein said laser light has a wavelength in a range from 730 to 820 nm.

10. A surface-emitting semiconductor laser element according to claim 9, wherein said laser light has a wavelength in a range from 770 to 800 nm.
